(19) United States
(12) Patent Application Publication
(10) Pub. No.: US 2016/0358827 A1
(43) Pub. Date: Dec. 8, 2016

(54) METHOD OF FORMING FIN-SHAPED STRUCTURE

(71) Applicant: UNITED MICROELECTRONICS CORP., Hsin-Chu City (TW)

(72) Inventors: Chih-Kai Hsu, Tainan City (TW); Ssu-I Fu, Kaohsiung City (TW); Yu-Hsiang Hung, Tainan City (TW); Wei-Chi Cheng, Kaohsiung City (TW); Jyh-Shyang Jenq, Pingtung County (TW)

(21) Appl. No.: 15/241,077

(22) Filed: Aug. 19, 2016

Related U.S. Application Data
(63) Continuation-in-part of application No. 14/519,146, filed on Oct. 21, 2014.

(51) Int. Cl. H01L 21/84; H01L 21/306; H01L 21/02; H01L 21/311; H01L 29/66; H01L 21/762; H01L 21/308

(52) U.S. Cl. CPC H01L 21/845; H01L 21/76202; H01L 21/30604; H01L 21/3085; H01L 21/31111; H01L 29/66795; H01L 21/7624; H01L 21/02238

(57) ABSTRACT

A method of forming a fin-shaped structure includes the following step. A substrate having a first area and a second area is provided. An epitaxial structure is formed in the first area. An epitaxial structure is formed in the second area after the epitaxial structure in the first area is formed, wherein the surface area of the epitaxial structure in the first area is different from the surface area of the epitaxial structure in the second area.

### CROSS REFERENCE TO RELATED APPLICATIONS

This application is a Continuation-In-Part (CIP) application of and claims the benefit of U.S. patent application Ser. No. 14/519,146, filed Oct. 21, 2014.

### BACKGROUND OF THE INVENTION

1. Field of the Invention

The present invention relates generally to a method of forming a fin-shaped structure, and more specifically to a method of forming a fin-shaped structure composed of epitaxial layers in different areas.

2. Description of the Prior Art

With increasing miniaturization of semiconductor devices, various multi-gate MOSFET devices have been developed. The multi-gate MOSFET is advantageous for the following reasons. Manufacturing processes of multi-gate MOSFET devices can be integrated into traditional logic device processes, and are therefore more compatible. In addition, since the three-dimensional structure of the multi-gate MOSFET increases the overlapping area between the gate and the substrate, the channel region is controlled more effectively. This therefore reduces drain-induced barrier lowering (DIBL) effects and short channel effects. Moreover, the channel region is longer for a similar gate length, so the current between the source and the drain is increased.

In the present semiconductor process, a localized oxidation isolation (LOCOS) or a shallow trench isolation (STI) is normally used to isolate each MOS. Due to the reduction in both design sizes and fabricating line widths of the semiconductor wafers, however, pits, crystal defects and longer bird's beaks in the LOCOS process will greatly affect the characteristics of the semiconductor wafer. In the same way, the field oxide produced in the LOCOS process occupies a larger volume, which affects the integration of the semiconductor wafer. Thus, in the submicron semiconductor processes, the STI process is widely used as an isolation technique to isolate each of the multi-gate MOSFET components, thanks to its smaller size and improved integration. The STI process works by forming shallow trench isolation structures between each fin-shaped structure to electrically isolate them from each other.

In modern multi-gate MOSFET processes, ion implantation processes and annealing processes may be performed below each fin-shaped structure and the substrate between each fin-shaped structure, to form channel stop layers with an opposite electrical type below them for electrically isolating transistors formed on each fin-shaped structure. Dopants imported during the ion implantation processes are insufficient, however, leading to circuit leakage caused by each of the fin-shaped structures being incompletely electrically isolated. Meanwhile, the fin-shaped structures in different areas may have different numbers, and it make loading effect occur while forming these fin-shaped structures.

### SUMMARY OF THE INVENTION

The present invention provides a method of forming a fin-shaped structure, which forms fin structures by epitaxy and the fin structures in different areas are formed respectively for avoiding loading effect, and thus improving the uniformity of the formed fin structures.

The present invention provides a method of forming a fin-shaped structure including the following steps. A substrate having a first area and a second area is provided. An epitaxial structure is formed in the first area. An epitaxial structure is formed in the second area after the epitaxial structure is formed in the first area, wherein the surface area of the epitaxial structure in the first area is different from the surface area of the epitaxial structure in the second area.

According to the above, the present invention provides a method of forming a fin-shaped structure, which forms fin structures composed of epitaxial layers indifferent areas respectively, so that occurring of loading effect in different areas, especially for areas with different surface areas or different numbers of fin structures, can be avoided. Hence, improves the uniformity of the fin structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-16 schematically depict cross-sectional views of a method of forming a fin-shaped structure according to an embodiment of the present invention.

### DETAILED DESCRIPTION

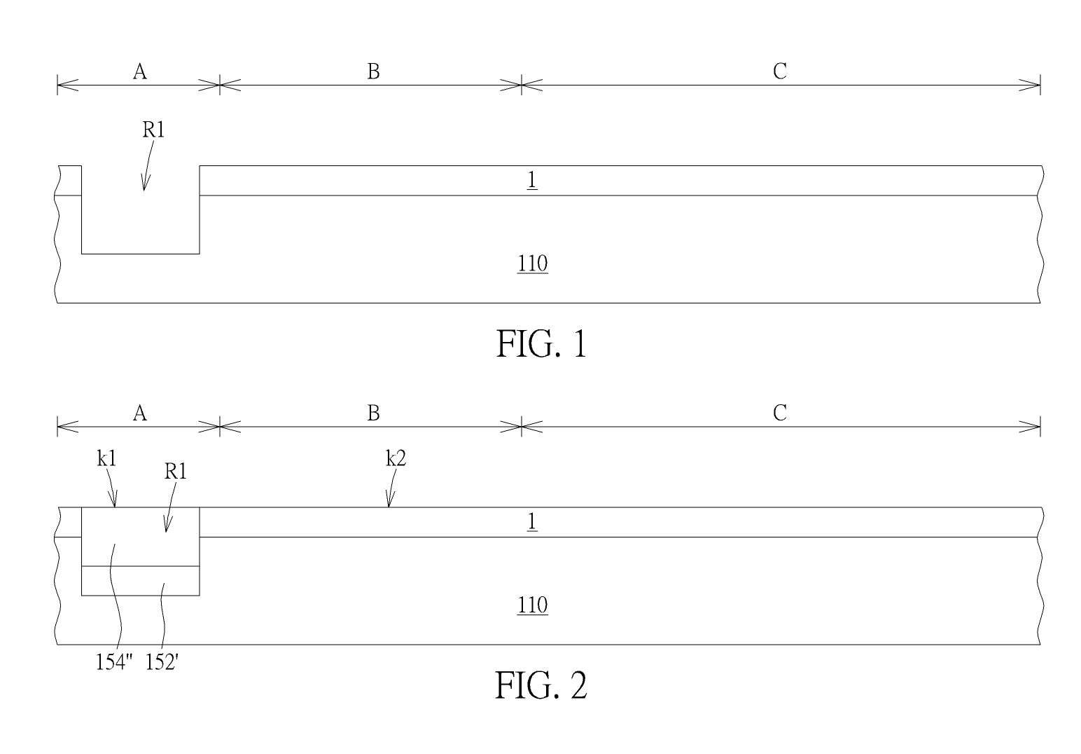

FIGS. 1-16 schematically depict cross-sectional views of a method of forming a fin-shaped structure according to an embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate, a silicon-on-insulator (SOI) substrate or a substrate containing epitaxial layers such as a P-type substrate having a P-type epitaxial layer with a thickness of 2.5 micrometers. In this embodiment, the substrate 110 has a first area A, a second area B and a third area C, but it is not limited thereto. In other embodiments, the substrate 110 may have other numbers of areas, depending upon practical devices. In this case, the surface areas of the epitaxial structures in the first area A, the second area B and the third area C are different, and different numbers of fin structures will be formed in the first area A, the second area B and the third area C, thus causing loading effect on layers for forming the fin structures. Thereby, the present invention provides a method of forming the fin structures in the first area A, the second area B and the third area C respectively described as follows, but it is not limited thereto.

Please refer to FIGS. 1-3, an epitaxial structure 150′ is formed in the first area A. As shown in FIG. 1, the substrate 110 of the first area A is etched to form a first recess R1. The substrate 110 of the first area A may be etched by a dry etching process, a wet etching process, or a dry etching and then wet etching process, depending upon requirements. More precisely, a first hard mask (not shown) may be blanketly formed on the substrate 110, and then the first hard mask (not shown) is patterned to form a first hard mask 1, thus the corresponding area of the substrate 110 for forming the first recess R1 being exposed. Then, the corresponding area of the substrate 110 is etched to form the first recess R1 by transferring the pattern of the first hard mask 1.

As shown in FIG. 2, a buffer epitaxial layer 152′ and an epitaxial layer 154″ are sequentially formed in the first recess R1. More precisely, a buffer epitaxial material (not shown) may cover the first recess R1 and the first hard mask 1 on the substrate 110; the buffer epitaxial material (not shown) exceeding from the first recess R1 may then by removed to form the buffer epitaxial layer 152′; the epitaxial layer (not shown) fills in the first recess R1 and blanketly covers the first hard mask 1 on the substrate 110; the epitaxial layer (not shown) exceeding from the first recess R1 is then removed to form the epitaxial layer 154″ in the first recess R1 and on the buffer epitaxial layer 152′. In this temporary state, a top surface k1 of the epitaxial layer 154″ trims a top surface k2 of the first hard mask 1, meaning the epitaxial layer (not shown) exceeding from the first recess R1 may be removed through planarizing, but it is not limited thereto.

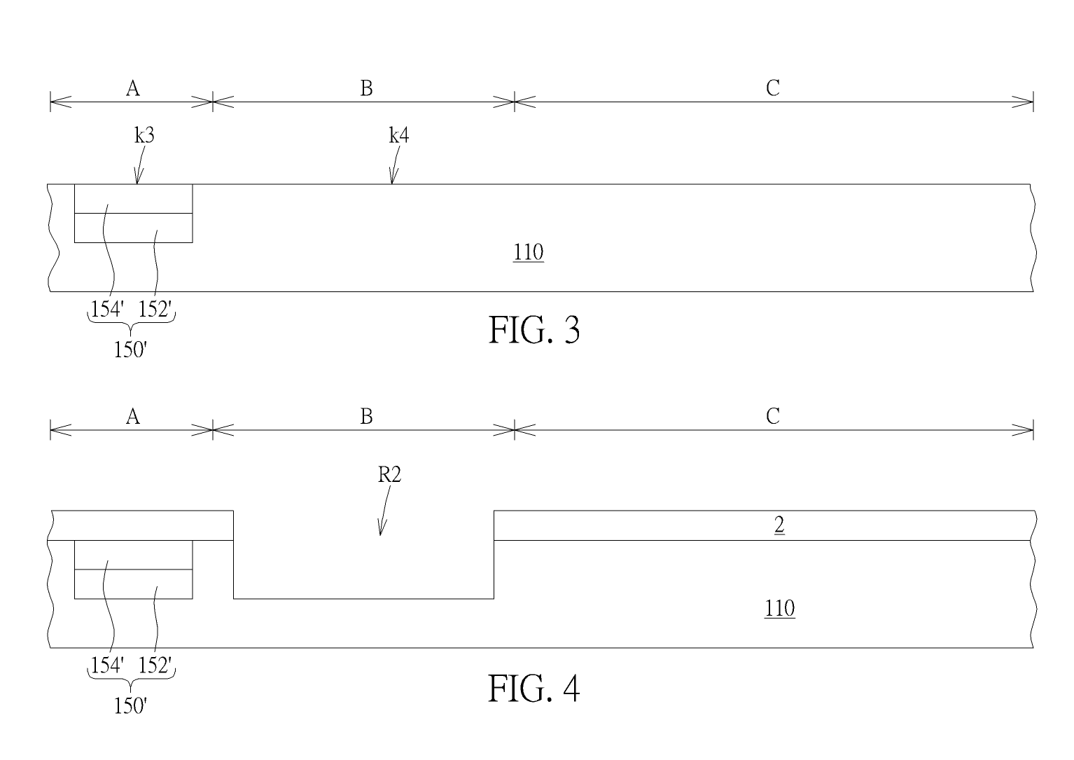

Thereafter, the first hard mask 1 is removed. In this embodiment, a part of the epitaxial layer 154″ is removed while the first hard mask 1 is removed, thereby the epitaxial layer 154′ being formed, as shown in FIG. 3. Thus, the buffer epitaxial layer 152′ and the epitaxial layer 154′ constitute an epitaxial structure 150′ only in and fills the first recess R1, but it is not restricted thereto. In this case, the first hard mask 1 and a part of the epitaxial layer 154″ exceeding from the first recess R1 are removed by planarizing, therefore a top surface k3 of the epitaxial structure 150′ trimming a top surface k4 of the substrate 110. In this way, the epitaxial structure 150′ constituted by the buffer epitaxial layer 152′ and the epitaxial layer 154′ from bottom to top in the first area A is formed completely. In some cases, the buffer epitaxial layer 152′ and the epitaxial layer 154′ may include trivalent elements, pentavalent elements or trivalent-pentavalent compounds, but it is not restricted thereto.

Please refer to FIGS. 4-6, an epitaxial structure 150′a is formed in the second area B. As shown in FIG. 4, the substrate 110 of the second area B is etched to forma second recess R2. The substrate 110 of the second area B may be etched by a dry etching process, a wet etching process, or a dry etching and then wet etching process, depending upon requirements. More precisely, a second hard mask (not shown) may cover the substrate 110 and the epitaxial structure 150′ in the first area A, and then the second hard mask (not shown) is patterned to form a second hard mask 2, thus the corresponding area of the substrate 110 for forming the second recess R2 being exposed. Then, the corresponding area of the substrate 110 is etched to form the second recess R2 by transferring the pattern of the second hard mask 2.

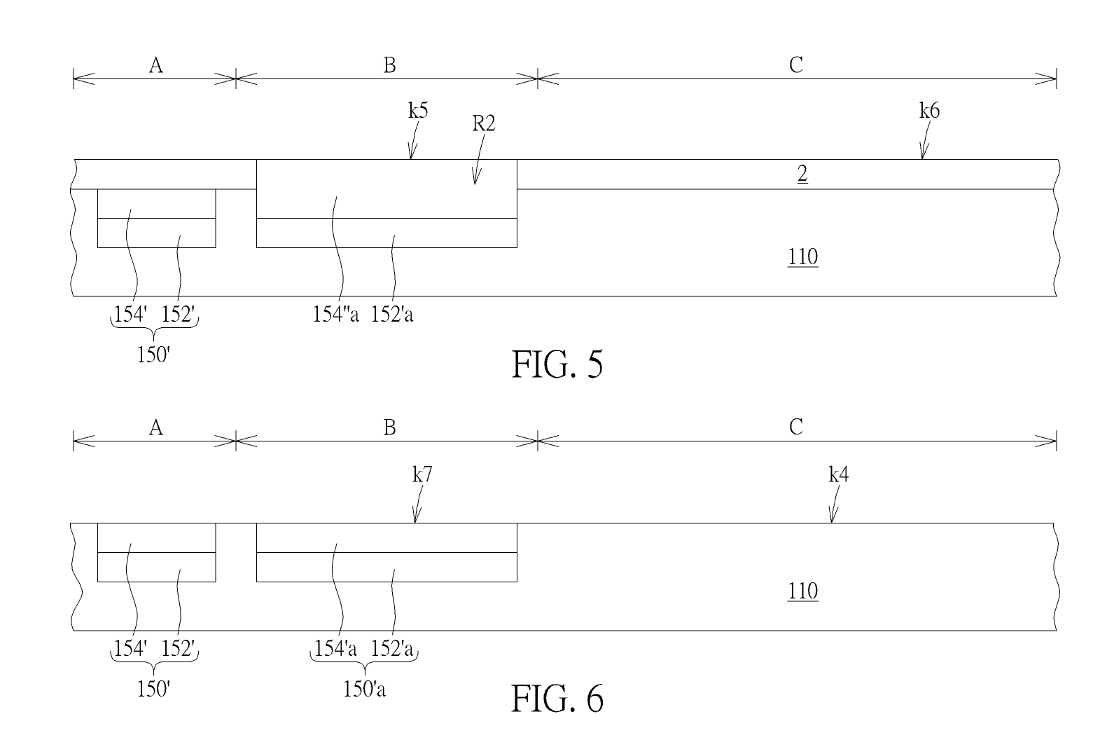

As shown in FIG. 5, a buffer epitaxial layer 152′a and an epitaxial layer 154″a are sequentially formed in the second recess R2. More precisely, a buffer epitaxial material (not shown) may cover the second recess R2 and the second hard mask 2 on the substrate 110; the buffer epitaxial material (not shown) exceeding from the second recess R2 may then by removed to form the buffer epitaxial layer 152′a; the epitaxial layer (not shown) fills in the second recess R2 and blanketly covers the second hard mask 2 on the substrate 110; the epitaxial layer (not shown) exceeding from the second recess R2 is then removed to form the epitaxial layer 154″a in the second recess R2 and on the buffer epitaxial layer 152′a. In this temporary state, a top surface k5 of the epitaxial layer 154″ trims a top surface k6 of the second hard mask 2, meaning the epitaxial layer (not shown) exceeding from the second recess R2 may be removed through planarizing, but it is not limited thereto.

Thereafter, the second hard mask 2 is removed. In this embodiment, a part of the epitaxial layer 154″a is removed while the second hard mask 2 is removed, thereby the epitaxial layer 154′a being formed, as shown in FIG. 6. Thus, the buffer epitaxial layer 152′a and the epitaxial layer 154′a constitute an epitaxial structure 150′a only in and fills the second recess R2, but it is not restricted thereto. In this case, the second hard mask 2 and a part of the epitaxial layer 154″a exceeding from the second recess R2 are removed by planarizing, therefore a top surface k7 of the epitaxial structure 150′a trimming the top surface k4 of the substrate 110. In this way, the epitaxial structure 150′a constituted by the buffer epitaxial layer 152′a and the epitaxial layer 154′a from bottom to top in the second area B is formed completely. In some cases, the buffer epitaxial layer 152′a and the epitaxial layer 154′a may include trivalent elements, pentavalent elements or trivalent-pentavalent compounds, but it is not restricted thereto.

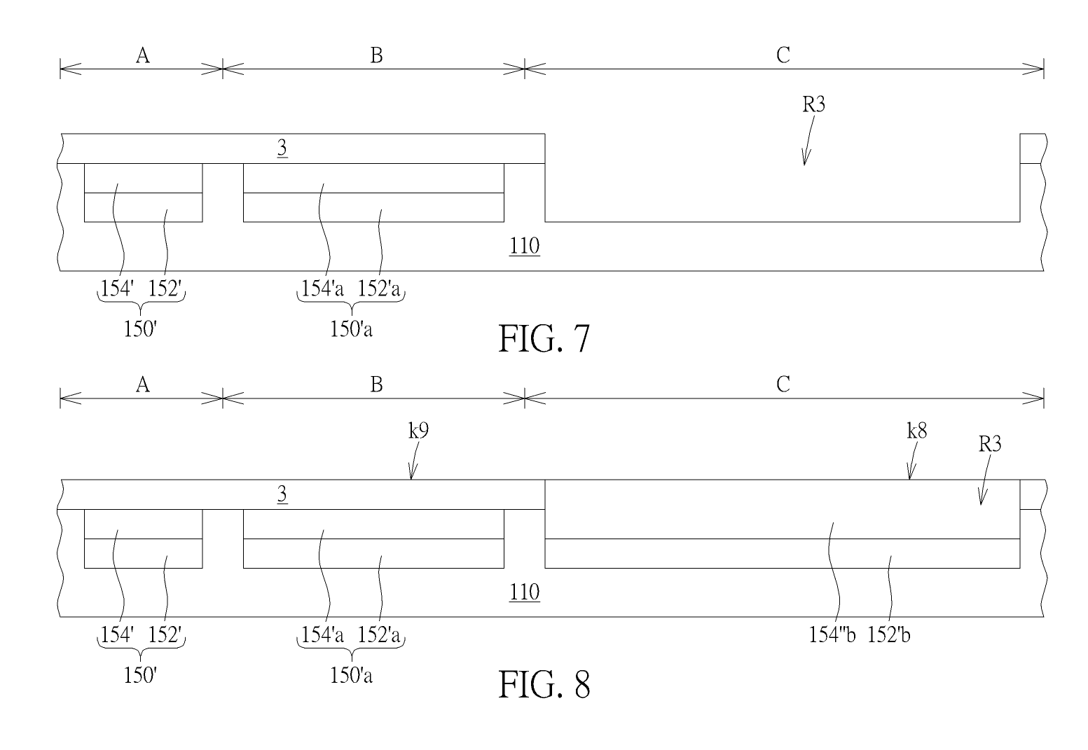

Likewise, please refer to FIGS. 7-9, an epitaxial structure 150′b is formed in the third area C. As shown in FIG. 7, the substrate 110 of the third area C is etched to form a third recess R3. The substrate 110 of the third area C may be etched by a dry etching process, a wet etching process, or a dry etching and then wet etching process, depending upon requirements. More precisely, a third hard mask (not shown) may cover the substrate 110, the epitaxial structure 150′ in the first area A and the epitaxial structure 150′a in the second area B, and then the third hard mask (not shown) is patterned to form a third hard mask 3, thus the corresponding area of the substrate 110 for forming the third recess R3 being exposed. Then, the corresponding area of the substrate 110 is etched to form the third recess R3 by transferring the pattern of the third hard mask 3.

As shown in FIG. 8, a buffer epitaxial layer 152′b and an epitaxial layer 154″b are sequentially formed in the third recess R3. More precisely, a buffer epitaxial material (not shown) may cover the third recess R3 and the third hard mask 3 on the substrate 110; the buffer epitaxial material (not shown) exceeding from the third recess R3 may then by removed to form the buffer epitaxial layer 152′b; the epitaxial layer (not shown) fills in the third recess R3 and blanketly covers the third hard mask 3 on the substrate 110; the epitaxial layer (not shown) exceeding from the third recess R3 is then removed to form the epitaxial layer 154″b in the third recess R3 and on the buffer epitaxial layer 152′b. In this temporary state, a top surface k8 of the epitaxial layer 154″b trims a top surface k9 of the third hard mask 3, meaning the epitaxial layer (not shown) exceeding from the third recess R3 maybe removed through planarizing, but it is not limited thereto.

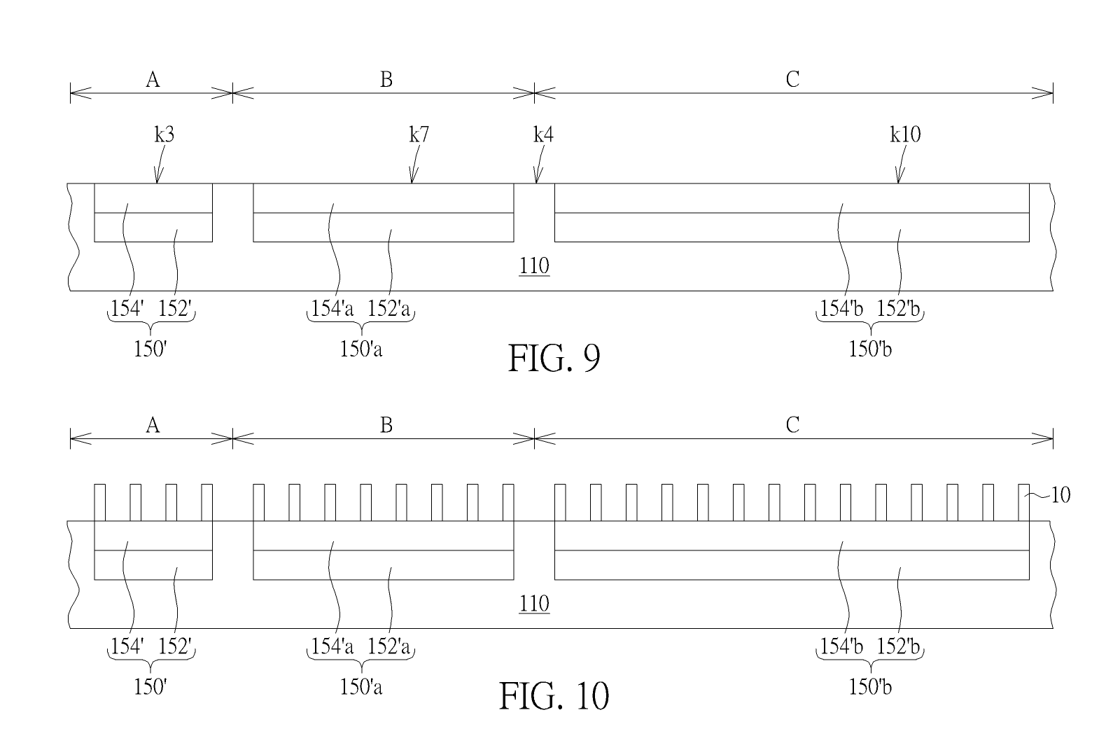

Thereafter, the third hard mask 3 is removed. In this embodiment, a part of the epitaxial layer 154″b is removed while the third hard mask 3 is removed, thereby the epitaxial layer 154′b being formed, as shown in FIG. 9. Thus, the buffer epitaxial layer 152′b and the epitaxial layer 154′b constitute an epitaxial structure 150′b only in and fills the third recess R3, but it is not restricted thereto. In this case, the third hard mask 3 and a part of the epitaxial layer 154″b exceeding from the third recess R3 are removed by planarizing, therefore a top surface k10 of the epitaxial structure 150′b trimming the top surface k4 of the substrate 110. In this way, the epitaxial structure 150′b constituted by the buffer epitaxial layer 152′b and the epitaxial layer 154′b from bottom to top in the third area C is formed completely. In some cases, the buffer epitaxial layer 152′b and the epitaxial layer 154′b may include trivalent elements, pentavalent elements or trivalent-pentavalent compounds, but it is not restricted thereto.

Above all, the epitaxial structure 150′, the epitaxial structure 150′a and the epitaxial structure 150′b have different surface areas. That is, the surface area of the epitaxial structure 150′b is larger than the surface area of the epitaxial structure 150′a, and the surface area of the epitaxial structure 150′a is larger than the surface area of the epitaxial structure 150′. By applying the method of the present invention (as shown in FIGS. 1-9), meaning forming the epitaxial structure 150′, the epitaxial structure 150′a and the epitaxial structure 150′b respectively, occurring of the loading effect while forming the epitaxial structure 150′, the epitaxial structure 150′a and the epitaxial structure 150′b having different surface areas can be avoided. Thereby, the uniformity of formed fin structures from the epitaxial structure 150′, the epitaxial structure 150′a and the epitaxial structure 150′b, such as the uniformity of the heights of the formed fin structures from the epitaxial structure 150′, the epitaxial structure 150′a and the epitaxial structure 150′b, can be improved. Preferably, the top surface k3 of the epitaxial structure 150′, the top surface k7 of the epitaxial structure 150′a, the top surface k10 of the epitaxial structure 150′b and the top surface k4 of the substrate 110 all trim to each other.

Then, the epitaxial structure 150′, the epitaxial structure 150′a and the epitaxial structure 150′b will be patterned to form fin structures in the first area A, the second area B and the third area C in the following steps. In this embodiment, the numbers of the fin structures in the first area A, the second area B and the third area C are different; that is, the number of the fin structures in the third area C is more than the number of the fin structures in the second area B, and the number of the fin structures in the second area B is more than the number of the fin structures in the first area A since the surface area of the epitaxial structure 150′b is larger than the surface area of the epitaxial structure 150′a, and the surface area of the epitaxial structure 150′a is larger than the surface area of the epitaxial structure 150′, but it is not limited thereto. The numbers of the fin structures in the first area A, the second area B and the third area C depend upon practical requirements.

A sidewall image transfer (SIT) technology is performed, but methods of forming fin structures are not restricted thereto. As shown in FIG. 10, spacers 10 are formed on the epitaxial structure 150′, the epitaxial structure 150′a and the epitaxial structure 150′b for transferring the patterns of the spacers 10 to the corresponding positions of the epitaxial structure 150′, the epitaxial structure 150′a and the epitaxial structure 150′b. The spacers 10 may be formed by methods such as forming mandrels (not shown) on the epitaxial structure 150′, the epitaxial structure 150′a and the epitaxial structure 150′b, forming the spacers 10 beside the mandrels and then removing the mandrels, wherein the mandrels may be composed of polysilicon while the spacers 10 may be composed of silicon nitride, but it is not restricted thereto.

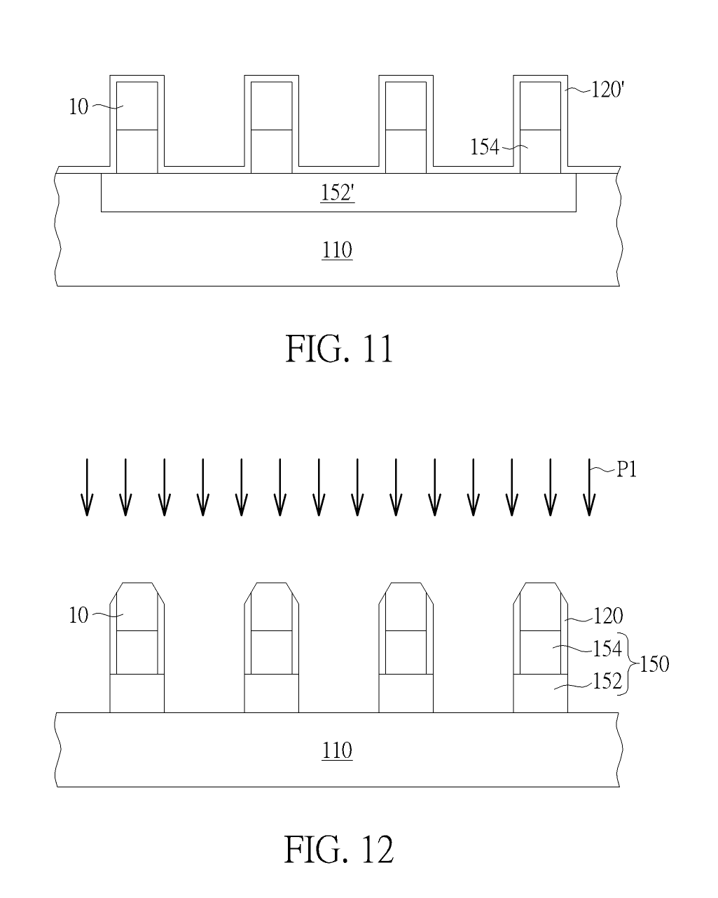

In this case, four fin structures will be formed in the first area A, eight fin structures will be formed in the second area B and fourteen fin structures will be formed in the third area C, but the numbers of the fin structures in the first area A, in the second area B and in the third area C are not restricted thereto. Due to the following methods of forming fin structures in the first area A, the second area B and the third area C being the same and the fin structures can be formed in the first area A, the second area B and the third area C at the same time, only fin structures in the first area A are depicted and described in FIGS. 11-16 for simplifying the present invention, but it is not limited thereto.

The epitaxial layer 154′ is patterned by methods such as etching, thereby top parts 154 of later formed fin structures being formed through transferring the patterns of the spacers 10, as shown in FIG. 11. In this case, only the epitaxial layer 154′ is patterned while the buffer epitaxial layer 152′ is reserved, but the processing step is not restricted thereto.

Thus, top parts 154 are formed on the buffer epitaxial layer 152′. In one case, the substrate 110 depicted in the figures is an area of a non-planar MOS transistor area while a planar MOS transistor area or a periphery circuit area forming other semiconductor components may be in other areas adjacent to this area, but are not depicted herein.

Then, a liner material 120′ conformally covers the spacers 10, the buffer epitaxial layer 152′ and the substrate 110. In this embodiment, the liner material 120′ is a nitride layer. In another embodiment, the liner material 120′ may be an antioxidant single layer or an antioxidant multilayer to prevent the top parts 154 covered by the liner material 120′ from being oxidized during later oxidation processes. The antioxidant single layer or the antioxidant multilayer may be silicon oxynitride, amorphous carbide or silicon carbide.

An etching process P1 may be performed to etch the liner material 120′ on the substrate 110 between the top parts 154, so bottom parts 152 of fin structures 150 and a liner 120 on each of the fin structures 150 are formed, as shown in FIG. 12. The top part 154 and the bottom part 152 constitute each of the fin structures 150. In other words, the top parts 154 of the fin structures 150 are formed from a top part of the epitaxial structure 150, meaning the epitaxial layer 154′, and the bottom parts 152 of the fin structures 150 are formed from a bottom part of the epitaxial structure 150, meaning the buffer epitaxial layer 152′. Meanwhile, the liners 120 are formed on sidewalls of each top part 154 of the fin structures 150 while exposing the bottom part 152 of each of the fin structures 150.

In this embodiment, the etching process P1 is a dry etching process, which is a non-isotropic etching process, so that fin structures 150 having vertical sidewalls can be formed, but this is not limited thereto. In another embodiment, a dry etching process may be first performed and then a wet etching process is performed. In this embodiment, the liners 120 and the bottom parts 152 of the fin structures 150 can be formed through performing the etching process P1 once. In another embodiment, a plurality of etching processes can be carried out. For example, the liner material 120′ is etched first to form the liners 120 on the sidewalls of the top parts 154, and the buffer epitaxial layer 152′ between each of the top parts 154 is then etched to form the bottom parts 152 of the fin structures 150. In this embodiment, the materials of the liner material 120′ and the spacers 10 are the same, but the thickness of the spacers 10 is larger than the thickness of the liner material 120′. This means the spacers 10 will not be consumed completely when the liner material 120′ is removed, which would damage the fin structures 150 below the spacers 10. In another embodiment, the materials of the liner material 120′ and the spacers 10 may be different, so they have different etching rates with respect to a specific etching gas/gas combination. By properly designing the thickness ratio, damages to the fin structures 150 can be avoided by reserving the spacers 10 after the liner material 120′ is removed.

As shown in FIG. 13, an oxide liner 30 maybe optionally formed beside the bottom parts 152 of the fin structures 150 to prevent the fin structures 150 from collapsing while performing a later oxidation process. In this embodiment, the oxide liner 30 conformally covers the whole fin structures 150 and the substrate 110 by methods such as a chemical oxide process, but this is not limited thereto. In another embodiment, the oxide liner 30 may be only formed beside the bottom parts 152 in other selective oxide processes.

An oxidation process P2 is then performed to oxidize the bottom parts 152 of the fin structures 150 and the substrate 110 between each of the fin structures 150 exposed by the liners 120, so that an oxide layer 130 is formed in the bottom parts 152 of the fin structures 150 and a part of the substrate 110 between each of the fin structures 150. Therefore, the oxide layer 130 is right below and between the top parts 154 of the fin structures 150. The oxide layer 130 has protruding parts 134 formed by oxidizing the bottom parts 152 of the fin structures 150. Sidewalls T1 of the protruding parts 134 trim sidewalls T2 of the liners 120. In this embodiment, the oxide layer 130 is formed by performing the oxidation process P2, which is preferably an O₂ steam thermal process or a dry thermal oxidation process, but is not limited thereto. In another embodiment, other isolating processes such as a nitridation process may be performed to form a dielectric layer with other isolation materials such as a nitride layer.

The fin structures 150 or the top parts 154 of the fin structures 150 (as the bottom parts 152 of the fin structures 150 are oxidized to be part of the oxide layer 130) and the substrate 110 sandwich the oxide layer 130 top and bottom. Therefore, the top part 154 of each of the fin structures 150 is a silicon-containing structure formed by epitaxy, and the bottom parts of the fin structures 150 is an oxide structure, which is a part of the oxide layer 130. In other words, apart of the oxide layer 130 extends to the fin structures 150.

It is emphasized that, since the top parts 154 of fin structures 150 are located on the oxide layer 130, and the oxide layer 130 is located directly below the top part 154 of each of the fin structures 150, and on the substrate 110 between the top part 154 of each of the fin structures 150, each of the fin structures 150 can electrically isolate the substrate 110 in the present invention, and each of the fin structures 150 are also electrically isolated with respect to each other. Transistors formed on the fin structures 150 are therefore electrically isolated from each other and the substrate 110. Moreover, the oxide layer 130 can be located only in this depicted area to be used for electrically isolating components in this area, without affecting components in/on the substrate (not shown) surrounding the oxide layer 130 or in other adjacent areas.

More precisely, the liner 120 is located on the top part 154 of each of the fin structures 150, enabling the bottom parts 152 of each of the fin structures 150 being oxidized to form a part of the oxide layer 130, so that transistors formed on the fin structures 150 can be electrically isolated from the substrate 110. Circuit leakage flowing downwards can therefore be avoided. As the fin structures 150 not covered by the liners 120 (such as the bottom parts 152 in this embodiment) will be oxidized, bottom surface S1 of the liners 120 trim with a top surface S2 of the oxide layer 130, but this is not limited thereto.

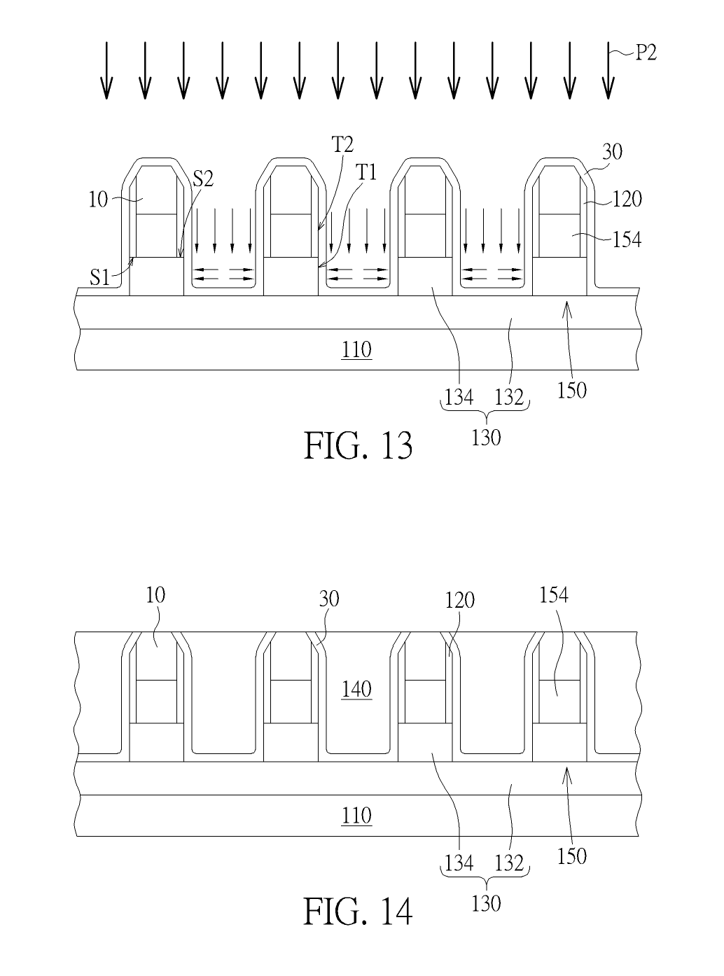

As shown in FIG. 14, an isolation structure 140 is formed on the oxide layer 130 between the fin structures 150. In this embodiment, the isolation structure 140 is a shallow trench isolation (STI) structure, which may be formed through a shallow trench isolation (STI) process. An isolation material (not shown) may be formed on the substrate 110 and entirely covers each of the fin structures 150 and the oxide layer 130. The isolation material (not shown) is planarized to trim with the spacers 10.

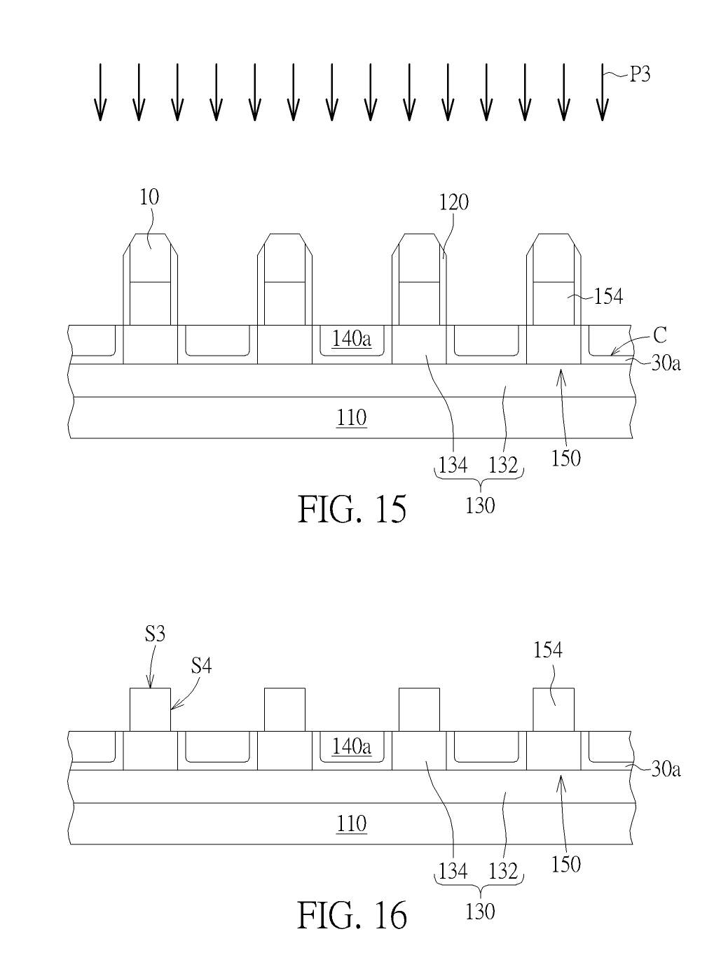

As shown in FIG. 15, an etching back process P3 may be performed to etch back the isolation structure 140 (or remove a top part of the isolation structure 140) until at least a part of fin structures 150 being exposed, so the isolation structure 140a and the oxide liner 30a are formed. The etching back process P3 maybe a dry etching process or a wet etching process depending upon practical requirements. It is noted that, although the oxide layer 130 or the oxide liner 30a of this embodiment is an oxide layer and the isolation structure 140a is a shallow trench isolation (STI) structure, which means that the isolation structure 140a is also an oxide layer, there is still an interface C because of their different forming methods. As the isolation structure 140 is etched back, the oxide liner 30 is also etched back and forms the oxide liner 130a which trims the isolation structure 140a.

The spacers 10 are removed to expose the top parts 154 of the fin structures 150, as shown in FIG. 16. The top parts 154 serve as gate channels to improve performances such as electrical mobility of a formed transistor on the fin structures 150, depending upon practical requirements. The top parts 154 may be composed of indium gallium arsenide (InGaAs), indium phosphide (InP), GaAs), indium gallium phosphide (InGaP), gallium arsenide (GaAs), aluminum gallium arsenide (AlGaAs), germanium (Ge), silicon germanium (SiGe), but it is note limited thereto.

Then, the liners 120 are removed after the top part of the isolation structure 140 are removed and the isolation structure 140a is formed.

This means the top parts 154 protrude from the isolation structure 140a for forming gate structures disposed thereon, wherein a top surface S3 and two sidewalls S4 of each of the top parts 154 are used as gate channels. In this embodiment, the whole sidewalls of the top parts 154 protrude from the isolation structure 140a, but this is not limited thereto. In another embodiment, only partial sidewalls of the top parts 154 protrude from the isolation structure 140.

In this embodiment, the top parts 154 are first formed, and a gate (not shown) is later formed across the top parts 154 and a source/drain (not shown) is later formed in each of the top parts 154.

To summarize, the present invention provides a method of forming a fin-shaped structure, which forms fin structures composed of epitaxial layers indifferent areas respectively, so that occurring of loading effect in different areas, especially for areas with different surface areas or different numbers of fin structures, can be avoided. Hence, improves the uniformity of the fin structures.

Moreover, the present invention may further include forming liners on sidewalls of top parts of the fin structures, and then oxidizing bottom parts of the fin structures exposed by the liners and a part of a substrate between each of the fin structures, so that the bottom parts of the fin structures and the part of the substrate can transform to form an oxide layer. The remaining fin structures (the top parts of the fin structures) can be electrically isolated from the substrate below and from each other. The bottom parts of fin structures may be oxidized by an oxidation process such as an O₂ steam annealing process, but this is not limited thereto. Furthermore, an oxide liner may be formed beside the bottom parts of the fin structures before the oxide layer is formed to prevent the fin structures from collapsing while the oxide layer is formed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a fin-shaped structure, comprising:
providing a substrate having a first area and a second area;
forming an epitaxial structure in the first area; and
forming an epitaxial structure in the second area after the epitaxial structure in the first area being formed, wherein the surface area of the epitaxial structure in the first area is different from the surface area of the epitaxial structure in the second area.

2. The method of forming a fin-shaped structure according to claim 1, the step of forming the epitaxial structure in the first area comprises:
etching the substrate of the first area to form a first recess; and
forming the epitaxial structure in the first recess.

3. The method of forming a fin-shaped structure according to claim 2, the step of etching the substrate of the first area to form the first recess comprises:
forming a first hard mask on the substrate;
patterning the first hard mask; and
etching the substrate of the first area to form the first recess by transferring the pattern of the first hard mask.

4. The method of forming a fin-shaped structure according to claim 3, further comprising:
removing the first hard mask after the epitaxial structure is formed in the first recess and before the epitaxial structure is formed in the second area.

5. The method of forming a fin-shaped structure according to claim 4, wherein the method of removing the first hard mask comprises planarizing the first hard mask and a part of the epitaxial structure exceeding from the first recess.

6. The method of forming a fin-shaped structure according to claim 2, the step of forming the epitaxial structure in first recess comprises:
filling a buffer epitaxial layer in the first recess and then filling an epitaxial layer on the buffer layer and in the first recess.

7. The method of forming a fin-shaped structure according to claim 6, the step of filling the buffer epitaxial layer in the first recess and then filling the epitaxial layer on the buffer layer and in the first recess comprises:
covering a buffer epitaxial material on the first recess and the substrate;
removing the buffer epitaxial material exceeding from the first recess, thereby the buffer epitaxial layer being formed;
filling the epitaxial layer in the first recess; and
removing the epitaxial layer exceeding from the first recess, thereby the epitaxial layer being formed.

8. The method of forming a fin-shaped structure according to claim 1, wherein each of the epitaxial structure comprises a buffer epitaxial layer and an epitaxial layer from bottom to top.

9. The method of forming a fin-shaped structure according to claim 8, wherein the buffer epitaxial layer and the epitaxial layer comprise trivalent elements, pentavalent elements or trivalent-pentavalent compounds.

10. The method of forming a fin-shaped structure according to claim 1, the step of forming the epitaxial structure in the second area after the epitaxial structure in the first area being formed comprises:
forming a second hard mask covering the substrate and the epitaxial structure in the first area; and
patterning the second hard mask in the second area;
etching the substrate of the second area to form a second recess by transferring the pattern of the second hard mask; and
forming the epitaxial structure in the second recess.

11. The method of forming a fin-shaped structure according to claim 10, further comprising:
removing the second hard mask after the epitaxial structure is formed in the second recess.

12. The method of forming a fin-shaped structure according to claim 1, further comprising:
forming fin structures from the epitaxial structure in first area and from the epitaxial structure in the second area.

13. The method of forming a fin-shaped structure according to claim 12, wherein the fin structures in the first area and in the second area formed at the same time.

14. The method of forming a fin-shaped structure according to claim 13, wherein the number of the fin structures in the first area is different from the number of the fin structures in the second area.

15. The method of forming a fin-shaped structure according to claim 12, further comprising:
oxidizing a part of the substrate and bottom parts of the fin structures to form an oxide layer right below and between top parts of the fin structures.

16. The method of forming a fin-shaped structure according to claim 15, wherein the step of forming fin structures from the epitaxial structure in first area and from the epitaxial structure in the second area comprise:
forming top parts of the fin structures from a top part of the epitaxial structure in the first area and from a top part of the epitaxial structure in the second area;
covering a liner material on the top parts of the fin structures and bottom parts of the epitaxial structures in the first area and in the second area; and
etching the liner material and the bottom parts of the epitaxial structures between the top parts of the fin structures, thereby the fin structures being formed, and liners on sidewalls of the top parts of the fin structures being formed.

17. The method of forming a fin-shaped structure according to claim 16, wherein the oxide layer has protruding parts formed by oxidizing the bottom parts of the fin structures, wherein sidewalls of the protruding parts trim sidewalls of the liners.

18. The method of forming a fin-shaped structure according to claim 16, further comprising:
forming an isolation structure beside the fin structures in the first area and in the second area.

19. The method of forming a fin-shaped structure according to claim 18, further comprising:
removing a top part of the isolation structure until at least a part of fin structures being exposed.

20. The method of forming a fin-shaped structure according to claim 19, further comprising:
removing the liners after the top part of the isolation structure being removed.
